(19) United States
(12) Patent Application Publication
(10) Pub. No.: US 2024/0332364 A1
(43) Pub. Date: Oct. 3, 2024

(54) SILICON CARBIDE EPITAXIAL SUBSTRATE, METHOD OF MANUFACTURING SILICON CARBIDE EPITAXIAL SUBSTRATE, AND METHOD OF MANUFACTURING SILICON CARBIDE SEMICONDUCTOR DEVICE

(71) Applicant: SUMITOMO ELECTRIC INDUSTRIES, LTD., Osaka (JP)

(72) Inventor: Taro NISHIGUCHI, Osaka (JP)

(73) Assignee: SUMITOMO ELECTRIC INDUSTRIES, LTD., Osaka (JP)

(21) Appl. No.: 18/573,490

(22) PCT Filed: Jun. 15, 2022
(86) PCT No.: PCT/JP2022/023984

§ 371 Date: Dec. 22, 2023

(30) Foreign Application Priority Data
Jul. 8, 2021 (JP) 2021-113366

(51) Int. Cl. H01L 29/16; H01L 21/02; H01L 29/34; H01L 29/36; H01L 29/66

(52) U.S. Cl. CPC H01L 29/1608; H01L 21/02378; H01L 21/02529; H01L 29/34; H01L 29/36; H01L 29/66068

(57) ABSTRACT

A silicon carbide epitaxial substrate includes a silicon carbide substrate, a silicon carbide epitaxial layer, and a bump. The silicon carbide epitaxial layer is located on the silicon carbide substrate. The bump is formed on the silicon carbide epitaxial layer. The silicon carbide epitaxial layer includes a main surface located opposite to a boundary surface between the silicon carbide substrate and the silicon carbide epitaxial layer, and a drift layer that constitutes the main surface. An area density of the bump is 1.0/cm² or less on the main surface. A height of the bump is 50 nm or more. A diameter of the bump is 5 μm or more and 30 μm or less. A polytype of silicon carbide of the bump is the same as a polytype of silicon carbide of the silicon carbide epitaxial layer.

### TECHNICAL FIELD

The present disclosure relates to a silicon carbide epitaxial substrate, a method of manufacturing the silicon carbide epitaxial substrate, and a method of manufacturing a silicon carbide semiconductor device. The present application claims priority based on Japanese Patent Application No. 2021-113366 filed on Jul. 8, 2021. The entire contents of the Japanese patent application are incorporated herein by reference.

### BACKGROUND ART

Japanese Patent Laying-Open No. 2018-39714 (PTL 1) describes a silicon carbide epitaxial wafer having a bump defect.

### CITATION LIST

### Patent Literature

PTL 1: Japanese Patent Laying-Open No. 2018-39714

### SUMMARY OF INVENTION

A silicon carbide epitaxial substrate according to the present disclosure includes a silicon carbide substrate, a silicon carbide epitaxial layer, and a bump. The silicon carbide epitaxial layer is located on the silicon carbide substrate. The bump is formed on the silicon carbide epitaxial layer. The silicon carbide epitaxial layer includes a main surface located opposite to a boundary surface between the silicon carbide substrate and the silicon carbide epitaxial layer, and a drift layer that constitutes the main surface. An area density of the bump is 1.0/cm² or less on the main surface. A height of the bump is 50 nm or more. A diameter of the bump is 50 nm or more and 30 μm or less. A polytype of silicon carbide of the bump is the same as a polytype of silicon carbide of the silicon carbide epitaxial layer.

A method of manufacturing a silicon carbide epitaxial substrate according to the present disclosure includes the following steps. A silicon carbide epitaxial layer is formed on a silicon carbide substrate under a condition of a first C/Si ratio. A surface-modified layer is formed on the silicon carbide epitaxial layer under a condition of a second C/Si ratio. The surface-modified layer is removed by hydrogen etching. The second C/Si ratio is less than the first C/Si ratio. The removing the surface-modified layer by the hydrogen etching is performed at a temperature of 1600° C. or more and 1800° C. or less for a time of 1 minute or more and 10 minutes or less.

### BRIEF DESCRIPTION OF DRAWINGS

FIG. 1 is a schematic plan view showing a configuration of a silicon carbide epitaxial substrate according to the present embodiment.

FIG. 2 is a schematic cross sectional view along a line II-II of FIG. 1.

FIG. 3 is an enlarged plan view of a region III in FIG. 1.

FIG. 4 is a schematic cross sectional view along a region IV-IV of FIG. 3.

FIG. 5 is an enlarged plan view of a region V in FIG. 1.

FIG. 6 is a schematic cross sectional view along a region VI-VI of FIG. 5.

FIG. 7 is a schematic plan view showing measurement positions for carrier concentration and thickness of a drift layer.

FIG. 8 is a partial cross sectional schematic view showing a configuration of a manufacturing apparatus for the silicon carbide epitaxial substrate.

FIG. 9 is a flowchart schematically showing a method of manufacturing the silicon carbide epitaxial substrate according to the present embodiment.

FIG. 10 is a schematic cross sectional view showing a step of preparing a silicon carbide substrate.

FIG. 11A is a schematic diagram showing changes in temperature and pressure of a reaction chamber over time.

FIG. 11B is a schematic diagram showing gas supply segments.

FIG. 12 is a schematic cross sectional view showing a step of forming a silicon carbide epitaxial layer on the silicon carbide substrate.

FIG. 13 is a schematic cross sectional view showing a step of forming a surface-modified layer on the silicon carbide epitaxial layer.

FIG. 14 is a flowchart schematically showing a method of manufacturing a silicon carbide semiconductor device according to the present embodiment.

FIG. 15 is a schematic cross sectional view showing a step of forming a body region.

FIG. 16 is a schematic cross sectional view showing a step of forming a source region.

FIG. 17 is a schematic cross sectional view showing a step of forming a trench in a second main surface of the silicon carbide epitaxial layer.

FIG. 18 is a schematic cross sectional view showing a step of forming a gate insulating film.

FIG. 19 is a schematic cross sectional view showing a step of forming a gate electrode and an interlayer insulating film.

FIG. 20 is a schematic cross sectional view showing a configuration of the silicon carbide semiconductor device according to the present embodiment.

### DETAILED DESCRIPTION

### Problem to be Solved by the Present Disclosure

An object of the present disclosure is to provide a silicon carbide epitaxial substrate, a method of manufacturing the silicon carbide epitaxial substrate, and a method of manufacturing a silicon carbide semiconductor device, so as to improve reliability of the silicon carbide semiconductor device.

### Advantageous Effect of the Present Disclosure

According to the present disclosure, it is possible to provide a silicon carbide epitaxial substrate, a method of manufacturing the silicon carbide epitaxial substrate, and a method of manufacturing a silicon carbide semiconductor device, so as to improve reliability of the silicon carbide semiconductor device.

### DESCRIPTION OF EMBODIMENTS

First, embodiments of the present disclosure will be listed and described.

(1) A silicon carbide epitaxial substrate 100 according to the present disclosure includes a silicon carbide substrate 11, a silicon carbide epitaxial layer 22, and a bump 20. Silicon carbide epitaxial layer 22 is located on silicon carbide substrate 11.

Bump 20 is formed on silicon carbide epitaxial layer 22. Silicon carbide epitaxial layer 22 includes a main surface 2 located opposite to a boundary surface 3 between silicon carbide substrate 11 and silicon carbide epitaxial layer 22, and a drift layer 32 that constitutes main surface 2. An area density of bump 20 is 1.0/cm² or less on main surface 2. A height of bump 20 is 50 nm or more. A diameter of bump 20 is 5 μm or more and 30 μm or less. A polytype of silicon carbide of bump 20 is the same as a polytype of silicon carbide of silicon carbide epitaxial layer 22.

(2) In silicon carbide epitaxial substrate 100 according to (1), an in-plane uniformity of a carrier concentration in drift layer 32 may be 15% or less.

(3) In silicon carbide epitaxial substrate 100 according to (1), an in-plane uniformity of a carrier concentration in drift layer 32 may be 7% or less.

(4) In silicon carbide epitaxial substrate 100 according to any one of (1) to (3), a diameter of main surface 2 may be 150 mm or more.

(5) In silicon carbide epitaxial substrate 100 according to any one of (1) to (4), the area density of bump 20 may be 0.5/cm² or less.

(6) In silicon carbide epitaxial substrate 100 according to any one of (1) to (5), an in-plane uniformity of a thickness of drift layer 32 may be 5% or less.

(7) In silicon carbide epitaxial substrate 100 according to (6), the in-plane uniformity of the thickness of drift layer 32 may be 3% or less.

(8) A method of manufacturing a silicon carbide semiconductor device according to the present disclosure includes the following steps. Silicon carbide epitaxial substrate 100 according to any one of (1) to (7) is prepared. Silicon carbide epitaxial substrate 100 is processed.

(9) A method of manufacturing a silicon carbide epitaxial substrate 100 according to the present disclosure includes the following steps. A silicon carbide epitaxial layer 22 is formed on a silicon carbide substrate 11 under a condition of a first C/Si ratio. A surface-modified layer 33 is formed on silicon carbide epitaxial layer 22 tinder a condition of a second C/Si ratio. Surface-modified layer 33 is removed by hydrogen etching. The second C/Si ratio is less than the first C/Si ratio. The removing surface-modified layer 33 by the hydrogen etching is performed at a temperature of 1600° C. or more and 1800° C. or less for a time of 1 minute or more and 10 minutes or less.

(10) In the method of manufacturing silicon carbide epitaxial substrate 100 according to (9), a bump 20 formed on silicon carbide epitaxial layer 22 is a first bump and a bump 20 formed on surface-modified layer 33 is a second bump, an area density of the first bump before the forming surface-modified layer 33 on silicon carbide epitaxial layer 22 may be more than 1.0/cm². An area density of the second bump may be 1.0/cm² or less. The area density of the first bump after the removing surface-modified layer 33 by the hydrogen etching may be less than the area density of the first bump before the forming surface-modified layer 33 on silicon carbide epitaxial layer 22.

(11) In the method of manufacturing silicon carbide epitaxial substrate 100 according to (10), the area density of the first bump before the forming surface-modified layer 33 on silicon carbide epitaxial layer 22 may be more than 2/cm².

(12) In the method of manufacturing silicon carbide epitaxial substrate 100 according to any one of (9) to (11), a thickness of surface-modified layer 33 in the forming surface-modified layer 33 on silicon carbide epitaxial layer 22 may be 0.2 μm or more and 1 μm or less.

(13) In the method of manufacturing silicon carbide epitaxial substrate 100 according to any one of (9) to (12), the first C/Si ratio may be 1.1 or more and 1.8 or less.

(14) In the method of manufacturing silicon carbide epitaxial substrate 100 according to any one of (9) to (13), the second C/Si ratio may be 0.85 or more and 0.95 or less.

### Details of Embodiments of Present Disclosure

Hereinafter, embodiments of the present disclosure will be described in detail with reference to figures. It should be noted that in the below-described figures, the same or corresponding portions are denoted by the same reference characters, and will not be described repeatedly. Regarding crystallographic indications in the present specification, an individual orientation is represented by [ ], a group orientation is represented by < >, and an individual plane is represented by ( ), and a group plane is represented by { }. In addition, a negative index is supposed to be crystallographically indicated by putting “-” (bar) above a numeral, but is indicated by putting the negative sign before the numeral in the present specification.

### (Silicon Carbide Epitaxial Substrate)

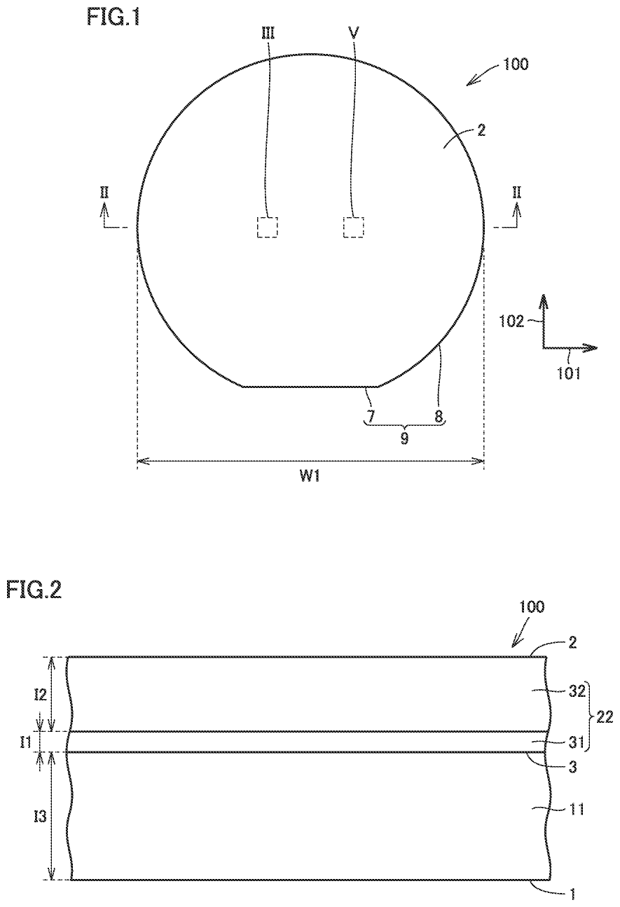

First, a configuration of a silicon carbide epitaxial substrate 100 according to the present embodiment will be described. FIG. 1 is a schematic plan view showing the configuration of silicon carbide epitaxial substrate 100 according to the present embodiment.

As shown in FIG. 1, silicon carbide epitaxial substrate 100 according to the present embodiment has a second main surface 2 and an outer peripheral side surface 9.

Second main surface 2 expands along each of a first direction 101 and a second direction 102. First direction 101 is, for example, a <11-20> direction. Second direction 102 is, for example, a <1-100> direction.

Second main surface 2 is a {0001} plane or a plane inclined with respect to the {0001} plane. An off angle of second main surface 2 with respect to the {0001} plane may be, for example, 5° or less. Specifically, second main surface 2 may be a plane inclined by an off angle of 5° or less with respect to a (0001) plane. Second main surface 2 may be a plane inclined by an off angle of 5° or less with respect to a (000-1) plane. An inclination direction (off direction) of second main surface 2 with respect to the {0001} plane is, for example, the <11-20> direction. The off angle of second main surface 2 with respect to the {0001} plane may be, for example, 4° or less, or 3° or less.

As shown in FIG. 1, outer peripheral side surface 9 has an orientation flat portion 7 and a circular are portion 8. Circular are portion 8 is contiguous to orientation flat portion 7. As shown in FIG. 1, orientation flat portion 7 extends along first direction 101 when viewed in a direction perpendicular to second main surface 2. A diameter W1 of second main surface 2 is 150 mm, for example. Diameter W1 may be 150 mm or more, or may be 200 mm or more. The upper limit of diameter W1 is not particularly limited, but may be 300 mm or less, for example. When viewed in the direction perpendicular to second main surface 2, diameter W1 is the maximum straight-line distance between two different points on outer peripheral side surface 9.

FIG. 2 is a schematic cross sectional view along a line II-II of FIG. 1. The cross section shown in FIG. 2 is perpendicular to second main surface 2 and parallel to first direction 101. As shown in FIG. 2, silicon carbide epitaxial substrate 100 according to the present embodiment has a silicon carbide substrate 11 and a silicon carbide epitaxial layer 22. Silicon carbide epitaxial layer 22 is located on silicon carbide substrate 11.

Silicon carbide epitaxial layer 22 has a buffer layer 31, a drift layer 32, and a boundary surface 3. Buffer layer 31 is in contact with silicon carbide substrate 11. Drift layer 32 is located on buffer layer 31. Drift layer 32 is in contact with buffer layer 31. Drift layer 32 constitutes second main surface 2. In silicon carbide epitaxial layer 22, second main surface 2 is located opposite to boundary surface 3. Boundary surface 3 is located at a boundary between silicon carbide substrate 11 and silicon carbide epitaxial layer 22.

A first main surface 1 is a backside surface of silicon carbide epitaxial substrate 100. Second main surface 2 is a front surface of silicon carbide epitaxial substrate 100. First main surface 1 is constituted of silicon carbide substrate 11. Second main surface 2 is constituted of silicon carbide epitaxial layer 22.

Each of silicon carbide substrate 11, buffer layer 31, and drift layer 32 is composed of, for example, a silicon carbide single crystal. Specifically, each of silicon carbide substrate 11, buffer layer 31, and drift layer 32 may be composed of, for example, silicon carbide of polytype 4H.

### (Bump)

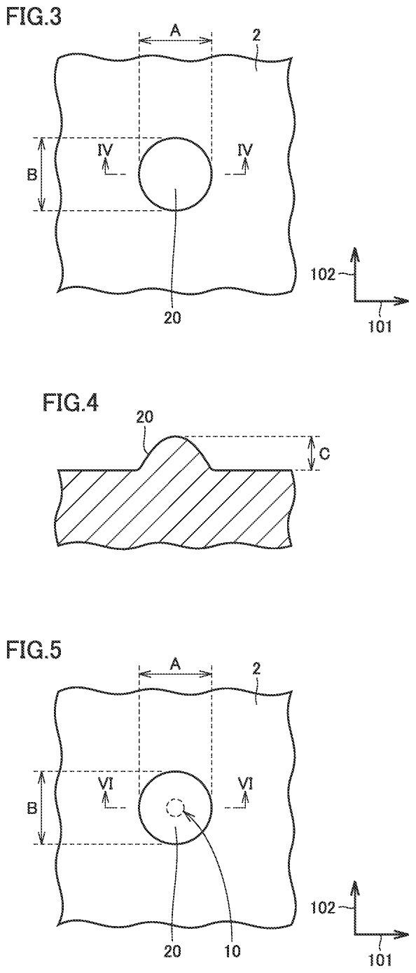

FIG. 3 is an enlarged plan view of a region III in FIG. 1. As shown in FIG. 3, for example, a bump 20 is located on second main surface 2 of silicon carbide epitaxial substrate 100. Bump 20 is formed on silicon carbide epitaxial layer 22. The polytype of silicon carbide of bump 20 is the same as the polytype of silicon carbide of silicon carbide epitaxial layer 22. When the polytype of silicon carbide of silicon carbide epitaxial layer 22 is 4H, the polytype of silicon carbide of bump 20 is 4H.

Whether or not the polytype of silicon carbide of bump 20 is the same as the polytype, of silicon carbide of silicon carbide epitaxial layer 22 can be determined using a photoluminescence imaging apparatus (model number: PLA-200-SMH5) provided by PHOTON Design Corporation. When the polytype of silicon carbide of bump 20 is the same as the polytype of silicon carbide of silicon carbide epitaxial layer 22, the contrast of a photoluminescence-imaging image of bump 20 is the same as the contrast of a photoluminescence-imaging image of silicon carbide epitaxial layer 22.

As shown in FIG. 3, when viewed in the direction perpendicular to second main surface 2, the shape of bump 20 is not particularly limited, but may be, for example, a substantially circular shape. A value obtained by dividing the width (first width A) of bump 20 along first direction 101 by the length (first length B) of bump 20 along second direction 102 may be 0.2 or more and 5 or less, or may be 0.5 or more and 2 or less, for example.

As shown in FIG. 3, the diameter of bump 20 is 5 μm or more and 30 μm or less when viewed in the direction perpendicular to second main surface 2. The lower limit of the diameter of bump 20 is not particularly limited, but may be 7 μm or more or may be 10 μm or more, for example. The upper limit of the diameter of bump 20 is not particularly limited, but may be 28 μm or less or may be 25 μm or less, for example. The diameter of bump 20 is the maximum distance between two points on the outer edge of bump 20.

FIG. 4 is a schematic cross sectional view along a region IV-IV of FIG. 3. As shown in FIG. 4, bump 20 is a protrusion formed on second main surface 2. When viewed in a cross sectional view, a side surface of bump 20 may be curved to protrude outward. The height (first height C) of bump 20 is 50 nm or more in the direction perpendicular to second main surface 2. In the direction perpendicular to second main surface 2, the upper limit of first height C is not particularly limited, but may be, for example, 200 nm or less or 100 nm or less. In the direction perpendicular to second main surface 2, the lower limit of first height C is not particularly limited, but may be, for example, 60 nm or more or 70 nm or more.

FIG. 5 is an enlarged plan view of a region V in FIG. 1. As shown in FIG. 5, bump 20 may be provided with a recess 10. From another viewpoint, it can be said that bump 20 may have a caldera shape. Bump 20 may be formed due to processing damage of silicon carbide substrate 11.

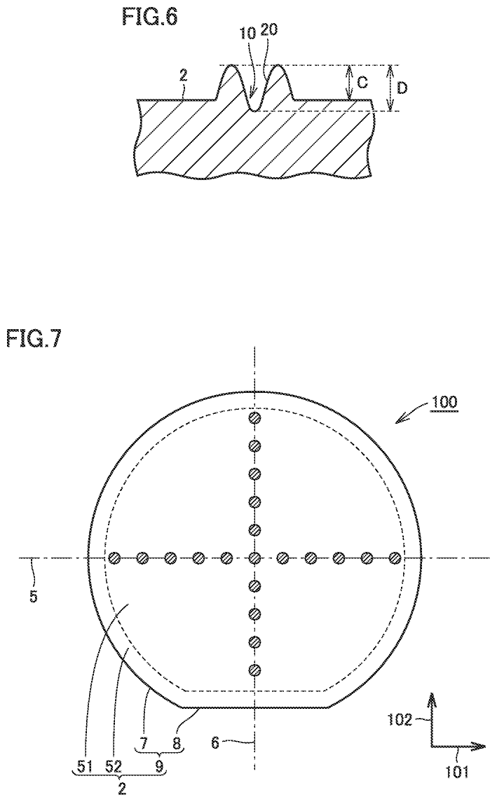

FIG. 6 is a schematic cross sectional view along a region V-VI of FIG. 5. As shown in FIG. 6, when viewed in a cross sectional view, recess 10 is formed in the vicinity of the center of bump 20. In the direction perpendicular to second main surface 2, the depth (first depth D) of recess 10 may be larger or smaller than the height (first height C) of bump 20. First depth D may be the same as first height C. In the direction perpendicular to second main surface 2, the lower limit of first depth D is not particularly limited, but may be, for example, 50 nm or more, 60 nm or more, or 70 nm or more.

On second main surface 2, the area density of bump 20 is 1.0/cm² or less. On second main surface 2, the upper limit of the area density of bump 20 is not particularly limited, but may be, for example, 0.8/cm or less, 0.6/cm² or less, 0.5/cm² or less, or 0.4/cm² or less. On second main surface 2, the lower limit of the area density of bump 20 is not particularly limited, but may be, for example, 0.01/cm² or more, or 0.02/cm² or more.

Bump 20 is specified by observing second main surface 2 of silicon carbide epitaxial substrate 100 using a defect inspection apparatus having a confocal differential interference microscope. As the defect inspection apparatus having the confocal differential interference microscope, for example, the WASAVI series “SICA 6×” provided by Lasertec can be used. The magnification of the objective lens is, for example, 10×. Second main surface 2 of silicon carbide epitaxial substrate 100 is irradiated with light having a wavelength of 546 nm from a light source such as a mercury xenon lamp, and reflected light of the light is observed using a light receiving element. Thus, a SICA image of second main surface 2 is obtained.

When a high bump 20 is observed using the SICA, the top surface of bump 20 is indicated to be relatively bright and the contrast value of the SICA image is relatively high. On the other hand, when a low bump 20 is observed using the SICA, the top surface of bump 20 is indicated to be relatively dark and the contrast value of the SICA image is relatively low. Bumps 20 having different contrasts are selected in advance, and the heights of bumps 20 are measured by an AFM (Atomic Force Microscope). Thus, the height of each bump 20 is estimated in accordance with the contrast (brightness/darkness) in the SICA image.

Bump 20 is defined based on the planar shape and height of bump 20. Bump 20 is specified based on the observed SICA image. “Thresh S”, which is an index of measurement sensitivity of the SICA, is 40, for example. The total number of bumps 20 is counted on the whole of second main surface 2. Second main surface 2 is constituted of an outer peripheral region 52 and a central region 51 (see FIG. 7). Outer peripheral region 52 is a region within 3 mm from outer peripheral side surface 9. Outer peripheral region 52 is excluded from the measurement region for the area density of bump 20 (edge exclusion). The area density of bump 20 is a value obtained by dividing the total number of bumps 20 in central region 51 by the area of central region 51.

### (In-Plane Uniformity of Carrier Concentration in Drift Layer)

Each of silicon carbide substrate 11, buffer layer 31, and drift layer 32 includes an impurity atom. Each of silicon carbide substrate 11, buffer layer 31, and drift layer 32 includes, for example, nitrogen (N) as an n type impurity. The conductivity type of each of silicon carbide substrate 11, buffer layer 31, and drift layer 32 is, for example, an n type (first conductivity type).

The average value of the carrier concentration of silicon carbide substrate 11 may be more than the average value of the carrier concentration of buffer layer 31. The average value of the carrier concentration of buffer layer 31 may be more than the average value of the carrier concentration in drift layer 32.

The in-plane uniformity of the carrier concentration in drift layer 32 is, for example, 15% or less. The in-plane uniformity of the carrier concentration is a value obtained by dividing the standard deviation of the carrier concentration by the average value of the carrier concentration. The upper limit of the in-plane uniformity of the carrier concentration in drift layer 32 is not particularly limited, but may be 10% or less, 7% or less, or 5% or less, for example. The lower limit of the in-plane uniformity of the carrier concentration in drift layer 32 is not particularly limited, but may be 0.5% or more, 1% or more, or 1.5% or more, for example.

The average value of the carrier concentration in drift layer 32 is, for example, 1×10¹⁵ cm⁻³ or more and 1×10¹⁷ cm⁻³ or less. The lower limit of the average value of the carrier concentration in drift layer 32 is not particularly limited, but may be, for example, 5×10¹⁵ cm⁻³ or more, or 1×10¹⁶ cm⁻³ or more. The upper limit of the average value of the carrier concentration in drift layer 32 is not particularly limited, but may be, for example, 5×10¹⁶ cm⁻³ or less, or 1×10¹⁶ cm⁻³ or less.

Next, a method of measuring the carrier concentration in drift layer 32 will be described.

The carrier concentration in drift layer 32 can be measured using a mercury probe type C (Capacitance)-V (Voltage) measurement apparatus. The mercury probe type C-V measurement apparatus is, for example, a C-V measurement apparatus (model number: CVmap92A) provided by Four Dimensions. The carrier concentration in drift layer 32 is measured by bringing the mercury probe into contact with second main surface 2. A measurement diameter of the mercury probe is about 1.2 mm. A measurement speed is about 1 minute per point.

### (In-Plane Uniformity of Thickness of Drift Layer)

The in-plane uniformity of the thickness of drift layer 32 may be 5% or less. The in-plane uniformity of the thickness of drift layer 32 is a value obtained by dividing the standard deviation of the thickness of drift layer 32 by the average value of the thickness of drift layer 32. The upper limit of the in-plane uniformity of the thickness of drift layer 32 is not particularly limited, but may be, for example, 4% or less, 3% or less, or 2% or less. The lower limit of the in-plane uniformity of the thickness of drift layer 32 is not particularly limited, but may be, for example, 0.1% or more, 0.3% or more, or 0.5% or more.

As shown in FIG. 2, the average value (second thickness I2) of the thickness of drift layer 32 may be, for example, 5 μm or more. The lower limit of second thickness 12 is not particularly limited, but may be, for example, 10 μm or more or 20 μm or more. The upper limit of second thickness I2 is not particularly limited, but may be, for example, 100 μm or less or 50 μm or less.

The average value (first thickness I1) of the thickness of buffer layer 31 may be less than second thickness I2. The thickness (third thickness I1) of silicon carbide substrate 11 may be more than first thickness I1. Third thickness I3 may be more than second thickness I2. Third thickness I3 is, for example, 350 μm or more and 500 μm or less.

Next, a method of measuring the thickness of drift layer 32 will be described.

The thickness of drift layer 32 can be measured using, for example, an FTIR (Fourier Transform InfraRed spectrometer). The measurement apparatus is, for example, a Fourier transform infrared spectrophotometer (IRPrestige-21) provided by Shimadzu Corporation. The thickness of the silicon carbide layer epitaxial layer is measured by the FTIR in accordance with an optical constant difference caused by a carrier concentration difference between drift layer 32 and buffer layer 31. A measurement wave number range is, for example, a range from 3400 cm⁻¹ to 2400 cm⁻³. A wave number interval is, for example, about 4 cm⁻¹.

FIG. 7 is a schematic plan view showing measurement positions for the carrier concentration in drift layer 32 and the thickness of drift layer 32. In FIG. 7, each of the measurement positions for the carrier concentration in drift layer 32 and the thickness of drift layer 32 is a region indicated by hatching. The measurement positions include positions of ten substantially equal parts into which a first line segment 5 is divided, first line segment 5 passing through the center of second main surface 2, first line segment 5 being parallel to first direction 101. Similarly, the measurement positions include positions of nine substantially equal parts into which a second line segment 6 is divided, second line segment 6 passing through the center of second main surface 2, second line segment 6 being parallel to second direction 102. The intersection of first line segment 5 and second line segment 6 is the center of second main surface 2. The intersection of first line segment 5 and second line segment 6 is one of the measurement positions.

As shown in FIG. 7, the carrier concentration in drift layer 32 is measured at each of a total of 20 measurement positions (regions indicated by hatchings) on second main surface 2. Next, the average value of the carrier concentration in drift layer 32 and the standard deviation of the carrier concentration in drift layer 32 are found. Similarly, the thickness of drift layer 32 is measured at each of a total of 20 measurement positions (regions indicated by hatchings) on second main surface 2. Next, the average value of the thickness of drift layer 32 and the standard deviation of the thickness of drift layer 32 are found. Outer peripheral region 52 is excluded from each measurement region for the carrier concentration in drift layer 32 and the thickness of drift layer 32 (edge exclusion).

### (Manufacturing Apparatus for Silicon Carbide Epitaxial Substrate)

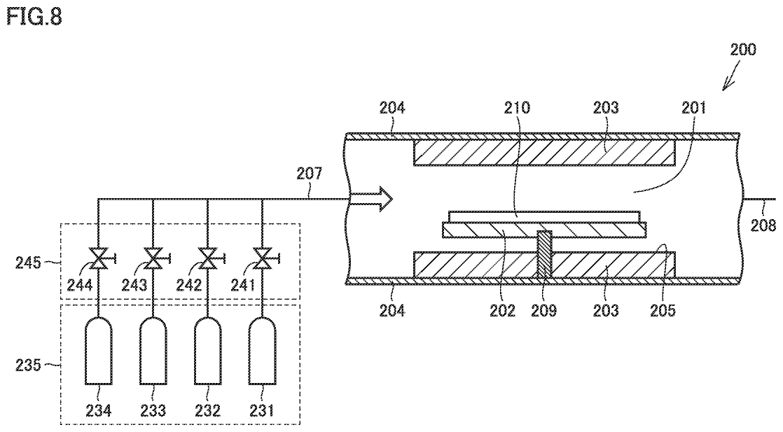

Next, a configuration of a manufacturing apparatus for silicon carbide epitaxial substrate 100 will be described. FIG. 8 is a partial cross sectional schematic view showing the configuration of the manufacturing apparatus for silicon carbide epitaxial substrate 100. Manufacturing apparatus 200 for silicon carbide epitaxial substrate 100 is, for example, a hot wall type horizontal CVD (Chemical Vapor Deposition) apparatus. As shown in FIG. 8, manufacturing apparatus 200 for silicon carbide epitaxial substrate 100 mainly has a reaction chamber 201, a gas supply unit 235, a control unit 245, a heating element 203, a quartz tube 204, a heat insulating material (not shown), and an induction heating coil (not shown).

Heating element 203 has, for example, a tubular shape and has reaction chamber 201 formed therein. Heating element 203 is composed of graphite, for example. Heating element 203 is provided inside quartz tube 204. The heat insulating material surrounds the outer periphery of heating element 203. The induction heating coil is wound along the outer peripheral surface of quartz tube 204, for example. The induction heating coil is configured to supply AC current by an external power supply (not shown). Thus, heating element 203 is inductively heated. As a result, reaction chamber 201 is heated by heating element 203.

Reaction chamber 201 is a space formed to be surrounded by inner wall surface 205 of heating element 203. A susceptor 210 that holds silicon carbide substrate 11 is provided in reaction chamber 201. Susceptor 210 is composed of silicon carbide. Silicon carbide substrate 11 is placed on susceptor 210. Susceptor 210 is disposed on a stage 202. Stage 202 is rotatably supported by a rotary shaft 209. When stage 202 is rotated, susceptor 210 is rotated.

Manufacturing apparatus 200 for silicon carbide epitaxial substrate 100 further has a gas introduction port 207 and a gas discharging port 208. Gas discharging port 208 is connected to a discharging pump (not shown). An arrow in FIG. 8 indicates flow of gas. The gas is introduced from gas introduction port 207 into reaction chamber 201 and is discharged from gas discharging port 208. Pressure in reaction chamber 201 is adjusted in accordance with a balance between a supply amount of the gas and a discharging amount of the gas.

Gas supply unit 235 is configured to supply a mixed gas including a source gas, a dopant gas, and a carrier gas to reaction chamber 201. Specifically, gas supply unit 235 includes, for example, a first gas supply unit 231, a second gas supply unit 232, a third gas supply unit 233, and a fourth gas supply unit 234.

First gas supply unit 231 is configured to supply a first gas including, for example, carbon atoms. First gas supply unit 231 is, for example, a gas cylinder having the first gas therein. The first gas is, for example, propane (C₃H₈) gas. The first gas may be, for example, methane (CH₄) gas, ethane (C₂H₆) gas, acetylene (C₂H₂) gas, or the like.

Second gas supply unit 232 is configured to supply a second gas including, for example, silicon atoms. Second gas supply unit 232 is, for example, a gas cylinder having the second gas therein. The second gas is, for example, silane (SiH₄) gas. The second gas may be a mixed gas of silane gas and gas other than silane.

Third gas supply unit 233 is configured to supply a third gas including, for example, nitrogen atoms. Third gas supply unit 233 is, for example, a gas cylinder having the third gas therein. The third gas is a doping gas. The third gas is, for example, ammonia gas. The ammonia gas is more likely to be thermally decomposed than nitrogen gas having a triple bond.

Fourth gas supply unit 234 is configured to supply a fourth gas (carrier gas) such as hydrogen, for example. Fourth gas supply unit 234 is, for example, a gas cylinder having hydrogen therein. The fourth gas may be argon gas.

Control unit 245 is configured to control a flow rate of the mixed gas supplied from gas supply unit 235 to reaction chamber 201. Specifically, control unit 245 may include a first gas flow rate control unit 241, a second gas flow rate control unit 242, a third gas flow rate control unit 243, and a fourth gas flow rate control unit 244. Each of the control units may be, for example, a MFC (Mass Flow Controller), Control unit 245 is disposed between gas supply unit 235 and gas introduction port 207.

### (Method of Manufacturing Silicon Carbide Epitaxial Substrate)

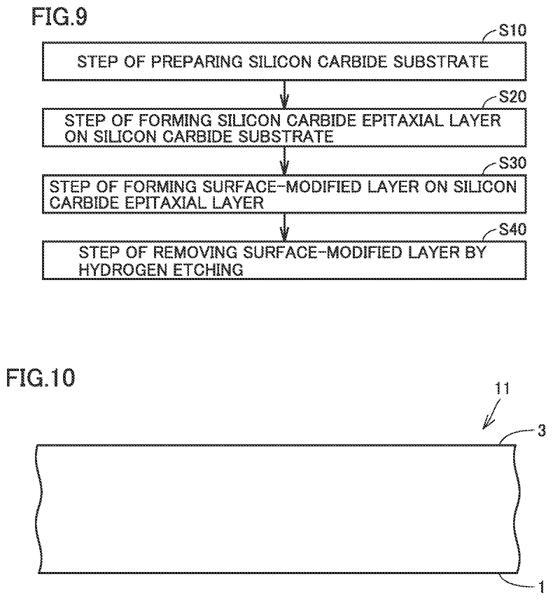

Next, a method of manufacturing silicon carbide epitaxial substrate 100 according to the present embodiment will be described. FIG. 9 is a flowchart schematically showing a method of manufacturing silicon carbide epitaxial substrate 100 according to the present embodiment. As shown in FIG. 9, the method of manufacturing silicon carbide epitaxial substrate 100 according to the present embodiment mainly has: a step (S10) of preparing silicon carbide substrate 11; a step (S20) of forming silicon carbide epitaxial layer 22 on silicon carbide substrate 11; a step (S30) of forming surface-modified layer 33 on silicon carbide epitaxial layer 22; and a step (S40) of removing surface-modified layer 33 by hydrogen etching. In the step (S40) of removing surface-modified layer 33 by the hydrogen etching, the whole of surface-modified layer 33 may be removed or may not be removed (in other words, only part of surface-modified layer 33 may be removed).

First, the step (S10) of preparing silicon carbide substrate 11 is performed. For example, an ingot composed of a silicon carbide single crystal manufactured by a sublimation method is sliced by a wire saw, and a surface of a silicon carbide substrate cut out is planarized by polishing or the like. Thus, silicon carbide substrate 11 is prepared. Silicon carbide substrate 11 is composed of, for example, silicon carbide of polytype 4H. The diameter of silicon carbide substrate 11 is 150 mm, for example. FIG. 10 is a schematic cross sectional view showing the step of preparing silicon carbide substrate 11. As shown in FIG. 10, silicon carbide substrate 11 has first main surface 1 and a third main surface 3. Third main surface 3 is located opposite to first main surface 1.

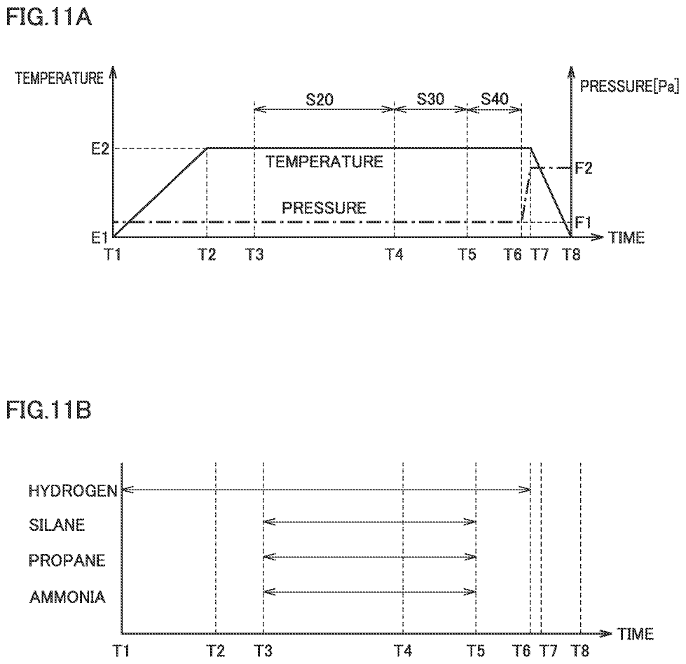

Next, the step (S20) of forming silicon carbide epitaxial layer 22 on silicon carbide substrate 11 is performed. FIG. 11A is a schematic diagram showing a change in each of temperature and pressure of the reaction chamber over time. In FIG. 11A, the temperature of the reaction chamber is indicated by a solid line. In FIG. 11A, the pressure in the reaction chamber is indicated by an alternate long and short dash line. FIG. 11B is a schematic diagram showing gas supply segments.

First, a temperature increasing step is performed. As shown in FIG. 11A, in a period from a first time point T1 to a second time point T2, the temperature of the reaction chamber is increased from a first temperature E1 to a second temperature E2. First temperature E1 is a room temperature (for example, 27° C.). Second temperature E2 is, for example, 1550° C. or more and 1750° C. or less. In the period from first time point T1 to second time point T2, the pressure in reaction chamber 201 is a first pressure F1. First pressure F1 is, for example, 10 Pa or more and 500 Pa or less. In the period from first time point T1 to second time point T2, hydrogen is introduced from fourth gas supply unit 234 into reaction chamber 201. The flow rate of hydrogen is, for example, 100 slm.

Next, a step of performing hydrogen etching onto silicon carbide substrate 11 is performed. In a period from second time point T2 to a third time point T3, the temperature of reaction chamber 201 is maintained at, for example, second temperature E2. In the period from second time point T2 to third time point T3, hydrogen is continuously introduced into reaction chamber 201. Thus, the hydrogen etching is performed onto third main surface 3 of silicon carbide substrate 11.

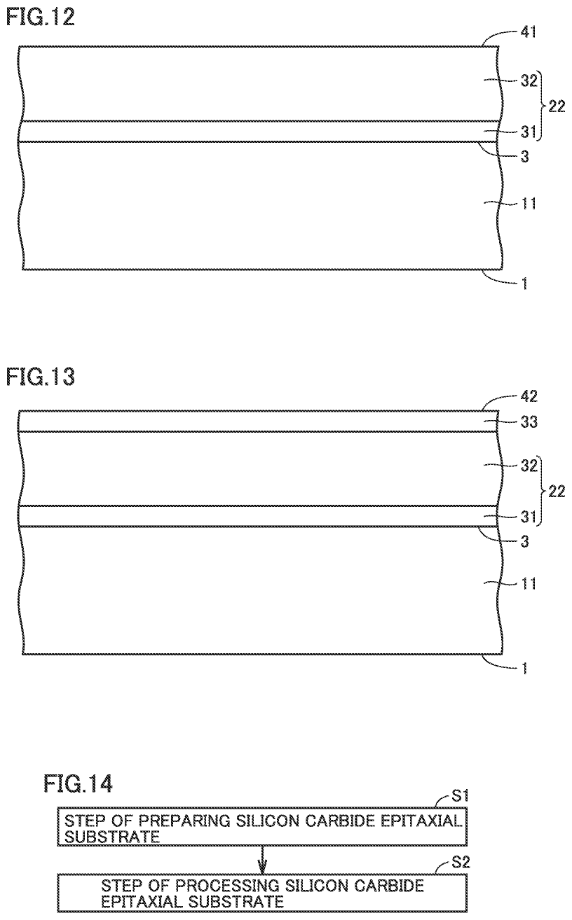

Next, the step (S20) of forming silicon carbide epitaxial layer 22 on silicon carbide substrate 11 is performed. FIG. 12 is a schematic cross sectional view showing the step of forming silicon carbide epitaxial layer 22 on silicon carbide substrate 11. Specifically, silicon carbide epitaxial layer 22 is formed on silicon carbide substrate 11 under a condition of a first C/Si ratio. As shown in FIG. 12, silicon carbide epitaxial layer 22 may include buffer layer 31 and drift layer 32. Drift layer 32 is formed on buffer layer 31. Silicon carbide epitaxial layer 22 may be constituted only of drift layer 32.

As shown in FIG. 11B at third time point T3, supply of each of silane, propane and ammonia is started. Specifically, each of the flow rates of silane and propane is controlled to attain a first C/Si ratio of for example, 1.1. The first C/Si ratio may be, for example, 1.1 or more and 1.8 or less. The flow rate of silane is, for example, 10 sccm or more and 500 sccm or less. The flow rate of propane is, for example, 10 sccm or more and 500 sccm or less. The flow rate of ammonia is, for example, 10 sccm or more and 500 sccm or less. It should be noted that the first C/Si ratio is a C/Si ratio when forming an outermost surface of silicon carbide epitaxial layer 22 in the growth of silicon carbide epitaxial layer 22. That is, the first C/Si ratio is a C/Si ratio immediately before forming surface-modified layer 33. In a period from third time point T3 to a fourth time point T4, the temperature of reaction chamber 201 may be maintained at second temperature E2.

When silicon carbide epitaxial layer 22 is formed under a high C/Si ratio, a large number of bumps 20 are formed on surface 41 of silicon carbide epitaxial layer 22. The area density of bump 20 on silicon carbide epitaxial layer 22 is more than 1.0/cm², for example. The lower limit of the area density of bump 20 on silicon carbide epitaxial layer 22 is not particularly limited, but may be, for example, more than 2/cm², more than 3/cm², or more than 5/cm². The upper limit of the area density of bump 20 on silicon carbide epitaxial layer 22 is not particularly limited, but may be 100/cm² or less or 50/cm² or less.

Next, the step (S30) of forming surface-modified layer 33 on silicon carbide epitaxial layer 22 is performed. FIG. 13 is a schematic cross sectional view showing the step of forming surface-modified layer 33 on silicon carbide epitaxial layer 22. Surface-modified layer 33 is formed on silicon carbide epitaxial layer 22 under a condition of a second C/Si ratio. Surface-modified layer 33 is a silicon carbide layer.

The thickness of surface-modified layer 33 is, for example, 0.2 μm or more and 1 μm or less. The lower limit of the thickness of surface-modified layer 33 is not particularly limited, but may be 0.25 μm or more or 0.3 μm or more, for example. The upper limit of the thickness of surface-modified layer 33 is not particularly limited, but may be 0.9 μm or less or 0.8 μm or less, for example.

At fourth time point T4, each of the flow rates of silane, propane and ammonia is adjusted. In the step of forming surface-modified layer 33, each of the flow rates of silane and propane is controlled to attain a C/Si ratio of, for example, 0.9. The second C/Si ratio may be, for example, 0.85 or more and 0.95 or less. In a period from fourth time point T4 to a fifth time point T5, the temperature of reaction chamber 201 may be maintained at second temperature E2. As shown in FIG. 11B, at fifth time point T5, the supply of each of silane, propane, and ammonia to reaction chamber 201 is stopped.

When surface-modified layer 33 is formed under a low C/Si ratio, bump 20 is unlikely to be formed on the surface (modified surface 42) of surface-modified layer 33. The area density of bump 20 on surface-modified layer 33 is, for example, 1.0/cm² or less. The lower limit of the area density of bump 20 on surface-modified layer 33 is not particularly limited, but may be, for example, 0.01/cm² or more, or 0.1/cm² or more. The upper limit of the area density of bump 20 on surface-modified layer 33 is not particularly limited, but may be 0.8/cm² or less, or 0.6/cm² or less.

The second C/Si ratio is less than the first C/Si ratio. The lower limit of a value obtained by subtracting the second C/Si ratio from the first C/Si ratio is not particularly limited, but may be, for example, 0.1 or more, or 0.2 or more. The upper limit of the value obtained by subtracting the second C/Si ratio from the first C/Si ratio is not particularly limited, but may be 1 or less or 0.8 or less.

Next, the step (S40) of removing surface-modified layer 33 by the hydrogen etching is performed. In a period from fifth time point T5 to a sixth time point T6, the temperature of reaction chamber 201 is maintained at, for example, second temperature E2. In the period from fifth time point T5 to sixth time point T6, hydrogen is continuously introduced into reaction chamber 201. Thus, surface-modified layer 33 is removed by the hydrogen etching. The step of removing surface-modified layer 33 by the hydrogen etching is performed at a temperature of 1600° C. or more and 1800° C. or less for a time of 1 minute or more and 10 minutes or less.

The area density of bump 20 on silicon carbide epitaxial layer 22 after the step (S40) of removing surface-modified layer 33 by the hydrogen etching may be less than the area density of bump 20 on silicon carbide epitaxial layer 22 before the step (S30) of forming surface-modified layer 33 on silicon carbide epitaxial layer 22. The area density of bump 20 on silicon carbide epitaxial layer 22 after the step (S40) of removing surface-modified layer 33 by the hydrogen etching may be less than the area density of bump 20 on surface-modified layer 33 after the step (S30) of forming surface-modified layer 33 on silicon carbide epitaxial layer 22.

The area density of bump 20 on silicon carbide epitaxial layer 22 after the step (S40) of removing surface-modified layer 33 by the hydrogen etching is, for example, 1.0/cm² or less. The lower limit of the area density of bump 20 on silicon carbide epitaxial layer 22 after the step (S40) of removing surface-modified layer 33 by the hydrogen etching is not particularly limited, but may be, for example, 0.01/cm² or more, or 0.1/cm² or more. The upper limit of the area density of bump 20 on silicon carbide epitaxial layer 22 after the step (S40) of removing surface-modified layer 33 by the hydrogen etching is not particularly limited, but may be 0.8/cm² or less, or 0.6/cm² or less.

The lower limit of the temperature of the step of removing surface-modified layer 33 by the hydrogen etching is not particularly limited, but may be, for example, 1620° C. or more or 1640° C. or more. The upper limit of the temperature of the step of removing surface-modified layer 33 by the hydrogen etching is not particularly limited, but may be 1780° C. or less or 1760° C. or less.

The lower limit of the period of time of the step of removing surface-modified layer 33 by the hydrogen etching is not particularly limited, but may be, for example, 1.5 minutes or more, or 2 minutes or more. The upper limit of the period of time of the step of removing surface-modified layer 33 by the hydrogen etching is not particularly limited, but may be 9 minutes or less or 8 minutes or less.

Next, a pressure increasing step is performed. In a period from sixth time point T6 to a seventh time point T7, the pressure in reaction chamber 201 is increased from first pressure F1 to a second pressure F2. Second pressure F2 is, for example, atmospheric pressure (for example, 101 kPa). The temperature of reaction chamber 201 may be maintained at second temperature E2.

Next, a temperature decreasing step is performed. In a period from seventh time point T7 to an eighth time point T8, the temperature of reaction chamber 201 is decreased from second temperature E2 to first temperature E1. The pressure of reaction chamber 201 may be maintained at second pressure F2. Next, silicon carbide epitaxial substrate 100 is removed from reaction chamber 201. Thus, the manufacturing process for silicon carbide epitaxial substrate 100 is completed. It should be noted that in the above description, silicon carbide substrate 11 is continuously disposed in reaction chamber 201 in the period of time from the step (S20) of forming silicon carbide epitaxial layer 22 on silicon carbide substrate 11 to the step (S40) of removing surface-modified layer 33 by the hydrogen etching; however, the method of manufacturing the silicon carbide epitaxial substrate according to the present disclosure is not limited to the above. Silicon carbide substrate 11 may be removed from reaction chamber 201 after each step.

### (Method of Manufacturing Silicon Carbide Semiconductor Device)

Next, a method of manufacturing a silicon carbide semiconductor device 400 according to the present embodiment will be described. FIG. 14 is a flowchart schematically showing the method of manufacturing silicon carbide semiconductor device 400 according to the present embodiment. As shown in FIG. 14, the method of manufacturing silicon carbide semiconductor device 400 according to the present embodiment mainly has: a step (S1) of preparing silicon carbide epitaxial substrate 100; and a step (S2) of processing silicon carbide epitaxial substrate 100.

First, the step (S1) of preparing silicon carbide epitaxial substrate 100 is performed. In the step (S1) of preparing silicon carbide epitaxial substrate 100, silicon carbide epitaxial substrate 100 according to the present embodiment is prepared (see FIG. 1).

Next, the step (S2) of processing silicon carbide epitaxial substrate 100 is performed. Specifically, the following process is performed onto silicon carbide epitaxial substrate 100. First, ion implantation is performed into silicon carbide epitaxial substrate 100. In silicon carbide epitaxial layer 22, for example, a body region 13 is formed.

FIG. 15 is a schematic cross sectional view showing a step of forming the body region. Specifically, a p type impurity such as aluminum is ion-implanted into second main surface 2 of silicon carbide epitaxial layer 22. Thus, body region 13 having p type conductivity is formed. A portion of silicon carbide layer 32 in which no body region 13 is formed serves as drift region 21. The thickness of body region 13 is 0.9 μm, for example.

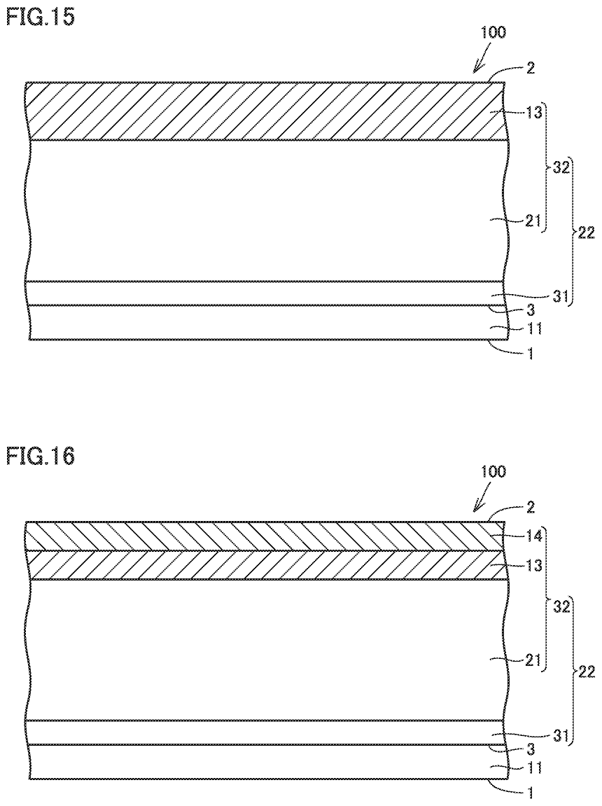

Next, a step of forming a source region is performed. FIG. 16 is a schematic cross sectional view showing the step of forming the source region. Specifically, an n type impurity such as phosphorus is ion-implanted into body region 13. Thus, a source region 14 having n type conductivity is formed. The thickness of source region 14 is 0.4 μm, for example. The concentration of the n type impurity in source region 14 is more than the concentration of the p type impurity in body region 13.

Next, a p type impurity such as aluminum is ion-implanted into source region 14, thereby forming a contact region 18. Contact region 18 is formed to extend through source region 14 and body region 13 so as to be in contact with drift region 21. The concentration of the p type impurity in contact region 18 is more than the concentration of the n type impurity in source region 14.

Next, activation annealing is performed to activate the ion-implanted impurities. The temperature of the activation annealing is preferably 1500° C. or more and 1900° C. or less, for example, about 1700° C. The time of the activation annealing is, for example, about 30 minutes. The atmosphere of the activation annealing is preferably an inert gas atmosphere, for example, an argon atmosphere.

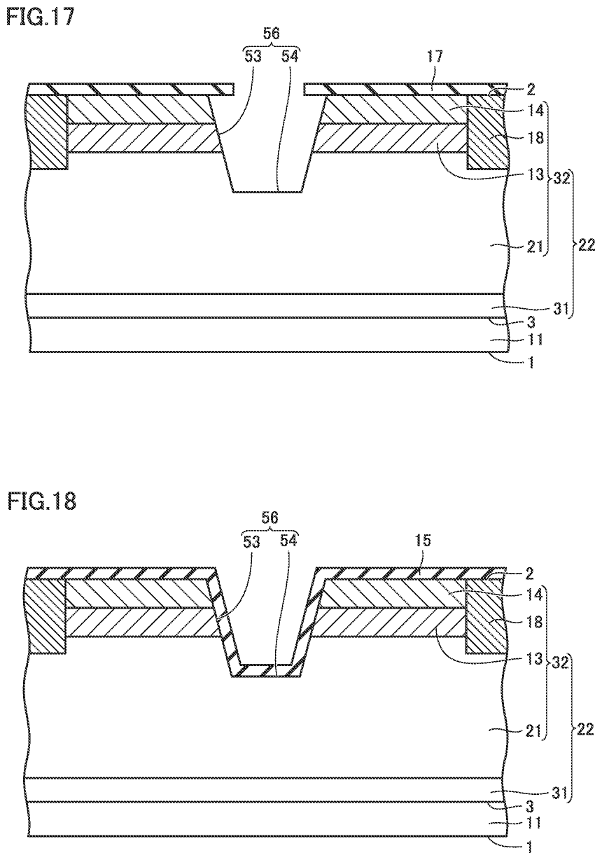

Next, a step of forming a trench in second main surface 2 of silicon carbide epitaxial layer 22 is performed. FIG. 17 is a schematic cross sectional view showing the step of forming the trench in second main surface 2 of silicon carbide epitaxial layer 22. A mask 17 provided with an opening is formed on second main surface 2 constituted of source region 14 and contact region 18. Mask 17 is used to remove source region 14, body region 13, and a portion of drift region 21 by etching. As the etching method, for example, reactive ion etching, particularly inductively coupled plasma reactive ion etching can be used. Specifically, inductively coupled plasma reactive ion etching using SF₆ or a mixed gas of SF₆ and O₂ as a reaction gas can be used, for example. By the etching, a recess is formed in second main surface 2.

Next, thermal etching is performed in the recess. The thermal etching can be performed, for example, by heating in an atmosphere including a reactive gas having at least one type of halogen atom with mask 17 being formed on second main surface 2. The at least one type of halogen atom includes at least one of chlorine (Cl) atom and fluorine (F) atom. The atmosphere includes, for example, Cl₂, BCl₃, SF₆ or CF₄. For example, the thermal etching is performed at a heat treatment temperature of, for example, 700° C. or more and 1000° C. or less using a mixed gas of chlorine gas and oxygen gas as the reaction gas. It should be noted that the reaction gas may include a carrier gas in addition to the above-described chlorine gas and oxygen gas. As the carrier gas, for example, nitrogen gas, argon gas, helium gas, or the like can be used.

As shown in FIG. 17, a trench 56 is formed in second main surface 2 by the thermal etching. Trench 56 is defined by a side wall surface 53 and a bottom wall surface 54. Side wall surface 53 is constituted of source region 14, body region 13, and drift region 21. Bottom wall surface 54 is constituted of drift region 21. Next, mask 17 is removed from second main surface 2.

Next, a step of forming a gate insulating film is performed. FIG. 18 is a schematic cross sectional view showing the step of forming the gate insulating film. Specifically, silicon carbide epitaxial substrate 100 provided with trench 56 in second main surface 2 is heated at a temperature of, for example, 1300° C. or more and 1400° C. or less in an atmosphere including oxygen. Thus, gate insulating film 15 is formed in contact with drift region 21 at bottom wall surface 54, in contact with each of drift region 21, body region 13, and source region 14 at side wall surface 53, and in contact with each of source region 14 and contact region 18 at second main surface 2.

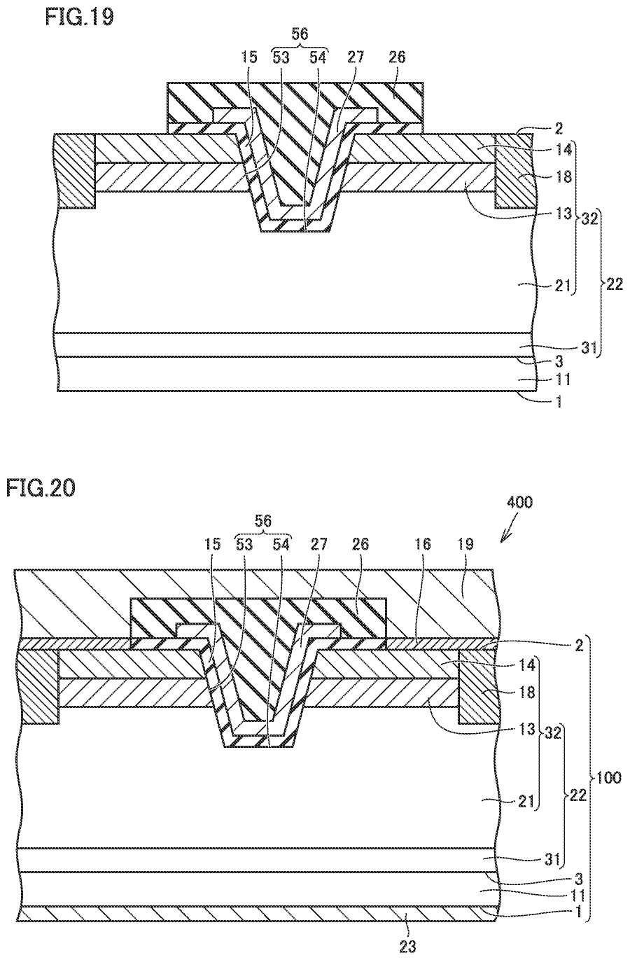

Next, a step of forming a gate electrode is performed. FIG. 19 is a schematic cross sectional view showing the step of forming the gate electrode and an interlayer insulating film. Gate electrode 27 is formed in contact with gate insulating film 15 inside trench 56. Gate electrode 27 is disposed inside trench 56, and is formed on gate insulating film 15 so as to face each of side wall surface 53 and bottom wall surface 54 of trench 56. Gate electrode 27 is formed by, for example, an LPCVD (Low Pressure Chemical Vapor Deposition) method.

Next, the interlayer insulating film is formed. Interlayer insulating film 26 covers gate electrode 27 and is formed in contact with gate insulating film 15. Interlayer insulating film 26 is formed by a chemical vapor deposition method, for example. Interlayer insulating film 26 is composed of, for example, a material including silicon dioxide. Next, portions of interlayer insulating film 26 and gate insulating film 15 are etched to form an opening over source region 14 and contact region 18. Thus, contact region 18 and source region 14 are exposed from gate insulating film 15.

Next, a step of forming a source electrode is performed. A source electrode 16 is formed in contact with each of source region 14 and contact region 18. Source electrode 16 is formed, for example, by a sputtering method. Source electrode 16 is composed of a material including, for example, Ti (titanium), Al (aluminum), and Si (silicon).

Next, alloying annealing is performed. Specifically, source electrode 16 in contact with each of source region 14 and contact region 18 is held at a temperature of 900° C. or more and 1100° C. or less for about 5 minutes, for example. Thus, at least a portion of source electrode 16 is silicided. Thus, source electrode 16 in ohmic contact with source region 14 is formed. Preferably, source electrode 16 is in ohmic contact with contact region 18.

Next, a source wiring 19 is formed. Source wiring 19 is electrically connected to source electrode 16. Source wiring 19 is formed to cover source electrode 16 and interlayer insulating film 26.

Next, a step of forming a drain electrode is performed. First, silicon carbide substrate 11 is polished at first main surface 1. Thus, the thickness of silicon carbide substrate 11 becomes thin. Next, a drain electrode 23 is formed. Drain electrode 23 is formed in contact with first main surface 1. In this way, silicon carbide semiconductor device 400 according to the present embodiment is manufactured.

FIG. 20 is a schematic cross sectional view showing the configuration of the silicon carbide semiconductor device according to the present embodiment. Silicon carbide semiconductor device 400 is, for example, a MOSFET (Metal Oxide Semiconductor Field Effect Transistor). Silicon carbide semiconductor device 400 mainly has silicon carbide epitaxial substrate 100, gate electrode 27, gate insulating film 15, source electrode 16, drain electrode 23, source wiring 19, and interlayer insulating film 26. Silicon carbide epitaxial substrate 100 has drift region 21, body region 13, source region 14, and contact region 18. Silicon carbide semiconductor device 400 may be, for example, an IGBT (Insulated Gate Bipolar Transistor) or the like.

Next, functions and effects of the methods of manufacturing silicon carbide epitaxial substrate 100 and silicon carbide semiconductor device 400 according to the present embodiment will be described.

When forming silicon carbide epitaxial layer 22 on silicon carbide substrate 11, bump 20 may be formed on the surface of silicon carbide epitaxial layer 22. When silicon carbide semiconductor device 400 is manufactured using silicon carbide epitaxial substrate 100 having bump 20 formed thereon, if the height of bump 20 is low (for example, about 20 nm), reliability of silicon carbide semiconductor device 400 is hardly affected. On the other hand, if the height of bump 20 is high (for example, 50 nm or more), quality of the oxide film formed on bump 20 may be deteriorated. As a result, the reliability of silicon carbide semiconductor device 400 may be significantly decreased.

As a result of diligent study, the inventors have found that the area density of bump 20 on main surface 2 of silicon carbide epitaxial substrate 100 can be reduced by optimizing a condition such as the C/Si ratio in the step of forming silicon carbide epitaxial layer 22. As a result, the reliability of silicon carbide semiconductor device 400 can be improved.

Silicon carbide epitaxial substrate 100 according to the present embodiment has silicon carbide substrate 11 and silicon carbide epitaxial layer 22. Silicon carbide epitaxial layer 22 is located on silicon carbide substrate 11. Silicon carbide epitaxial layer 22 includes main surface 2 located opposite to boundary surface 3 between silicon carbide substrate 11 and silicon carbide epitaxial layer 22, and drift layer 32 that constitutes main surface 2. The area density of bump 20 is 1.0/cm² or less on main surface 2. The height of bump 20 is 50 nm or more. The diameter of bump 20 is 5 μm or more and 30 μm or less. The polytype of silicon carbide of bump 20 is the same as the polytype of silicon carbide of silicon carbide epitaxial layer 22. Thus, the area density of bump 20 is reduced on main surface 2 of silicon carbide epitaxial substrate 100. Therefore, the reliability of silicon carbide semiconductor device 400 manufactured using silicon carbide epitaxial substrate 100 can be improved.

As a result of diligent study, the inventors have found that the in-plane uniformity of the carrier concentration in silicon carbide epitaxial layer 22 can be improved while reducing the area density of bump 20 on main surface 2 of silicon carbide epitaxial substrate 100 by further optimizing the condition such as the C/Si ratio in the step of forming silicon carbide epitaxial layer 22. As a result, a yield of silicon carbide semiconductor device 400 can be improved while improving the reliability of silicon carbide semiconductor device 400.

Silicon carbide epitaxial substrate 100 according to the present embodiment has silicon carbide substrate 11 and silicon carbide epitaxial layer 22. Silicon carbide epitaxial layer 22 is located on silicon carbide substrate 11. Silicon carbide epitaxial layer 22 includes main surface 2 located opposite to boundary surface 3 between silicon carbide substrate 11 and silicon carbide epitaxial layer 22, and drift layer 32 that constitutes main surface 2. The area density of bump 20 is 1.0/cm² or less on main surface 2. The height of bump 20 is 50 nm or more. The diameter of bump 20 is 5 μm or more and 30 μm or less. The polytype of silicon carbide of bump 20 is the same as the polytype of silicon carbide of silicon carbide epitaxial layer 22. The in-plane uniformity of the carrier concentration in drift layer 32 is 15% or less. Thus, the area density of bump 20 is reduced on main surface 2 of silicon carbide epitaxial substrate 100, and the in-plane uniformity of the carrier concentration in drift layer 32 is improved. Therefore, the yield of silicon carbide semiconductor device 400 can be improved while improving the reliability of silicon carbide semiconductor device 400 manufactured using silicon carbide epitaxial substrate 100.

Further, as a result of study by paying attention to a relation between the area density of bump 20 and the in-plane uniformity of the carrier concentration the inventors have obtained the following knowledge to find the method of manufacturing silicon carbide epitaxial substrate 100 according to the present embodiment. That is, when silicon carbide epitaxial layer 22 is formed on silicon carbide substrate 11 under a condition of a high C/Si ratio, the in-plane uniformity of the carrier concentration in silicon carbide epitaxial layer 22 is improved, but the area density of bump 20 on main surface 2 of silicon carbide epitaxial layer 22 becomes high. Conversely, when silicon carbide epitaxial layer 22 is formed on silicon carbide substrate 11 under a condition of a low C/Si ratio, the area density of bump 20 on main surface 2 of silicon carbide epitaxial layer 22 is reduced, but the in-plane uniformity of the carrier concentration in silicon carbide epitaxial layer 22 is deteriorated.

The method of manufacturing silicon carbide epitaxial substrate 100 according to the present embodiment has the following steps. Silicon carbide epitaxial layer 22 is formed on silicon carbide substrate 11 under the condition of the first C/Si ratio. Surface-modified layer 33 is formed on silicon carbide epitaxial layer 22 under the condition of the second C/Si ratio. Surface-modified layer 33 is removed by the hydrogen etching. The second C/Si ratio is less than the first C/Si ratio. The step of removing surface-modified layer 33 by the hydrogen etching is performed at a temperature of 1600° C. or more and 1800° C. or less for a time of 1 minute or more and 10 minutes or less.

By forming silicon carbide epitaxial layer 22 on silicon carbide substrate 11 under the condition of the first C/Si ratio, the in-plane uniformity of the carrier concentration in silicon carbide epitaxial layer 22 is improved. Next, by forming surface-modified layer 33 on silicon carbide epitaxial layer 22 under the condition of the second C/Si ratio, the area density of bump 20 on surface-modified layer 33 is reduced. By removing surface-modified layer 33 by the hydrogen etching under the particular condition, the area density of bump 20 can be reduced on main surface 2 of silicon carbide epitaxial layer 22. This makes it possible to improve the in-plane uniformity of the carrier concentration in silicon carbide epitaxial layer 22 while reducing the area density of bump 20 on main surface 2 of silicon carbide epitaxial substrate 100. As a result, the yield of silicon carbide semiconductor device 400 can be improved while improving the reliability of silicon carbide semiconductor device 400.

### (Sample Preparation)

First, silicon carbide epitaxial substrates 100 according to samples 1 to 3 were prepared. Silicon carbide epitaxial substrate 100 according to sample 1 was manufactured using the method of manufacturing silicon carbide epitaxial substrate 100 according to the present embodiment. On the other hand, regarding silicon carbide epitaxial substrate 100 according to each of samples 2 and 3, the step (S30) of forming surface-modified layer 33 on silicon carbide epitaxial layer 22 and the step (S40) of removing surface-modified layer 33 by the hydrogen etching were not performed. Further, regarding silicon carbide epitaxial substrate 100 according to each of samples 2 and 3, the hydrogen etching step after the temperature increasing step was also not performed.

Manufacturing conditions for silicon carbide epitaxial substrates 100 according to samples 1 to 3 were as follows. The temperature of the chamber during the epitaxial growth was 1660° C. The pressure in the chamber during the epitaxial growth was 100 Pa. The thickness of silicon carbide epitaxial layer 22 was 12 μm. The flow rate of ammonia was 100 sccm. The flow rate of hydrogen was 100 slm.

Manufacturing conditions for silicon carbide epitaxial substrate 100 according to sample 1 were as follows. In the step (S20) of forming silicon carbide epitaxial layer 22 on silicon carbide substrate 11, the first C/Si ratio was 1.1. The flow rate of silane was 109 sccm. The flow rate of propane was 40 sccm. In the step (S30) of forming surface-modified layer 33 on silicon carbide epitaxial layer 22, the second C/Si ratio was 0.9. The flow rate of silane was 133 sccm. The flow rate of propane was 40 sccm.

Manufacturing conditions for silicon carbide epitaxial substrate 100 according to sample 2 were as follows. In the step (S20) of forming silicon carbide epitaxial layer 22 on silicon carbide substrate 11, the first C/Si ratio was 1.1. The flow rate of silane was 109 sccm. The flow rate of propane was 40 sccm.

Manufacturing conditions for silicon carbide epitaxial substrate 100 according to sample 3 were as follows. In the step (S20) of forming silicon carbide epitaxial layer 22 on silicon carbide substrate 11, the first C/Si ratio was 0.9. The flow rate of silane was 133 sccm. The flow rate of propane was 40 sccm.

### (Measurement Methods)

The area density of bump 20 on main surface 2 of each silicon carbide epitaxial substrate 100 was measured. The area density of bump 20 was measured using the WASAVI series “SICA 6×” provided by Lasertec. The area density of bump 20 was measured in the manner described above.

The in-plane uniformity of the carrier concentration of silicon carbide epitaxial layer 22 was measured. The in-plane uniformity of the carrier concentration of silicon carbide epitaxial layer 22 is a value obtained by dividing the standard deviation of the carrier concentration of silicon carbide epitaxial layer 22 by the average value of the carrier concentration of silicon carbide epitaxial layer 22. The carrier concentration in silicon carbide epitaxial layer 22 was measured using a C-V measurement apparatus (model number: CVmap92A) provided by Four Dimensions.

The in-plane uniformity of the thickness of silicon carbide epitaxial layer 22 was measured. The in-plane uniformity of the thickness of silicon carbide epitaxial layer 22 is a value obtained by dividing the standard deviation of the thickness of silicon carbide epitaxial layer 22 by the average value of the thickness of silicon carbide epitaxial layer 22. The thickness of silicon carbide epitaxial layer 22 was measured using a Fourier transform infrared spectrophotometer (IRPrestige-21) provided by Shimadzu Corporation

### (Measurement Results)

TABLE 1

| | | | | In-Plane | |
|---|---|---|---|---|---|
| | | | Area | Uniformity | In-Plane |
| | First | Second | Density | of Carrier | Uniformity |
| | C/Si | C/Si | of Bump | Concentration | of Thickness |
| | Ratio | Ratio | (/cm²) | (%) | (%) |
| Sample 1 | 1.1 | 0.9 | 0.6 | 3.3 | 3.6 |
| Sample 2 | 1.1 | — | 36 | 3.4 | 4.0 |
| Sample 3 | 0.9 | — | 0.7 | 16.0 | 4.0 |

Table 1 shows the area density of bump 20 on main surface 2 of silicon carbide epitaxial substrate 100 according to each of samples 1 to 3, the in-plane uniformity of the carrier concentration of silicon carbide epitaxial layer 22, and the in-plane uniformity of the thickness of silicon carbide epitaxial layer 22.

As shown in Table 1, in silicon carbide epitaxial substrate 100 according to sample 1, the area density of bump 20 was 0.6/cm², the in-plane uniformity of the carrier concentration was 3.3%, and the in-plane uniformity of the thickness was 3.6%. In silicon carbide epitaxial substrate 100 according to sample 1, each of the in-plane uniformity of the carrier concentration of silicon carbide epitaxial layer 22 and the in-plane uniformity of the thickness of silicon carbide epitaxial layer 22 was improved while reducing the area density of bump 20.

In silicon carbide epitaxial substrate 100 according to sample 2, the area density of bump 20 was 36/cm the in-plane uniformity of the carrier concentration was 3.4%, and the in-plane uniformity of the thickness was 4.0%. In silicon carbide epitaxial substrate 100 according to sample 2, each of the in-plane uniformity of the carrier concentration of silicon carbide epitaxial layer 22 and the in-plane uniformity of the thickness of silicon carbide epitaxial layer 22 was improved; however, the area density of bump 20 was increased.

In silicon carbide epitaxial substrate 100 according to sample 3, the area density of bump 20 was 0.7/cm² the in-plane uniformity of the carrier concentration was 16.0%, and the in-plane uniformity of the thickness was 4.0%. In silicon carbide epitaxial substrate 100 according to sample 3, the area density of bump 20 was reduced; however, the in-plane uniformity of the carrier concentration of silicon carbide epitaxial layer 22 was deteriorated. As described above, it was confirmed that by using the method of manufacturing silicon carbide epitaxial substrate 100 according to the present embodiment, each of the in-plane uniformity of the carrier concentration of silicon carbide epitaxial layer 22 and the in-plane uniformity of the thickness of silicon carbide epitaxial layer 22 is improved while reducing the area density of bump 20.

The embodiments and examples disclosed herein are illustrative and non-restrictive in any respect. The scope of the present invention is defined by the terms of the claims, rather than the embodiments described above, and is intended to include any modifications within the scope and meaning equivalent to the terms of the claims.

### REFERENCE SIGNS LIST

1: first main surface; 2: main surface (second main surface); 3: boundary surface (third main surface); 5: first line segment; 6: second line segment; 7: orientation flat portion; 8: circular are portion; 9: outer peripheral side surface; 10: recess; 11: silicon carbide substrate: 13: body region: 14: source region; 15: gate insulating film; 16: source electrode; 17: mask; 18: contact region; 19: source wiring; 20: bump; 21: drift region; 22: silicon carbide epitaxial layer; 23: drain electrode; 26: interlayer insulating film; 27: gate electrode; 31: buffer layer; 32: drift layer (silicon carbide layer); 33: surface-modified layer; 41: surface; 42: modified surface; 51: central region; 52: outer peripheral region; 53: side wall surface; 54: bottom wall surface; 56: trench; 100: silicon carbide epitaxial substrate; 101: first direction; 102: second direction; 200: manufacturing apparatus; 201: reaction chamber; 202: stage; 203: heating element: 204: quartz tube; 205: inner wall surface; 207: gas introduction port; 208: gas discharging port; 209: rotary shaft; 210: susceptor; 231: first gas supply unit; 232: second gas supply unit; 233: third gas supply unit; 234: fourth gas supply unit; 235: gas supply unit; 241: first gas flow rate control unit; 242: second gas flow rate control unit; 243: third gas flow rate control unit; 244: fourth gas flow rate control unit; 245: control unit; 400: silicon carbide semiconductor device; A: first width; B: first length; C: first height; D: first depth; E1: first temperature; E2: second temperature; F1: first pressure; F2: second pressure; I1: first thickness; I2: second thickness; I3: third thickness: T1: first time point; T2: second time point; T3: third time point; T4: fourth time point; T5: fifth time point; T6: sixth time point; T7: seventh time point; T8: eighth time point; W1: diameter.

1. A silicon carbide epitaxial substrate comprising:
a silicon carbide substrate;
a silicon carbide epitaxial layer located on the silicon carbide substrate; and
a bump formed on the silicon carbide epitaxial layer, wherein
the silicon carbide epitaxial layer includes a main surface located opposite to a boundary surface between the silicon carbide substrate and the silicon carbide epitaxial layer, and a drift layer that constitutes the main surface,
an area density of the bump is 1.0/cm² or less on the main surface,
a height of the bump is 50 nm or more,
a diameter of the bump is 5 μm or more and 30 μm or less, and
a polytype of silicon carbide of the bump is the same as a polytype of silicon carbide of the silicon carbide epitaxial layer.

2. The silicon carbide epitaxial substrate according to claim 1, wherein an in-plane uniformity of a carrier concentration in the drift layer is 15% or less.

3. The silicon carbide epitaxial substrate according to claim 1, wherein an in-plane uniformity of a carrier concentration in the drift layer is 7% or less.

4. The silicon carbide epitaxial substrate according to claim 1, wherein a diameter of the main surface is 150 mm or more.

5. The silicon carbide epitaxial substrate according to claim 1, wherein the area density of the bump is 0.5/cm² or less.

6. The silicon carbide epitaxial substrate according to claim 1, wherein an in-plane uniformity of a thickness of the drift layer is 5% or less.

7. The silicon carbide epitaxial substrate according to claim 6, wherein the in-plane uniformity of the thickness of the drift layer is 3% or less.

8. A method of manufacturing a silicon carbide semiconductor device, the method comprising:
preparing the silicon carbide epitaxial substrate according to claim 1; and
processing the silicon carbide epitaxial substrate.

9. A method of manufacturing a silicon carbide epitaxial substrate, the method comprising:
forming a silicon carbide epitaxial layer on a silicon carbide substrate under a condition of a first C/Si ratio;
forming a surface-modified layer on the silicon carbide epitaxial layer under a condition of a second C/Si ratio; and
removing the surface-modified layer by hydrogen etching, wherein
the second C/Si ratio is less than the first C/Si ratio, and
the removing the surface-modified layer by the hydrogen etching is performed at a temperature of 1600° C. or more and 1800° C. or less for a time of 1 minute or more and 10 minutes or less.

10. The method of manufacturing the silicon carbide epitaxial substrate according to claim 9, wherein
a bump formed on the silicon carbide epitaxial layer is a first bump, and a bump formed on the surface-modified layer is a second bump,
an area density of the first bump before the forming the surface-modified layer on the silicon carbide epitaxial layer is more than 1.0/cm²,
an area density of the second bump is 1.0/cm² or less, and
the area density of the first bump after the removing the surface-modified layer by the hydrogen etching is less than the area density of the first bump before the forming the surface-modified layer on the silicon carbide epitaxial layer.

11. The method of manufacturing the silicon carbide epitaxial substrate according to claim 10, wherein the area density of the first bump before the forming the surface-modified layer on the silicon carbide epitaxial layer is more than 2/cm².

12. The method of manufacturing the silicon carbide epitaxial substrate according to claim 9, wherein a thickness of the surface-modified layer in the forming the surface-modified layer on the silicon carbide epitaxial layer is 0.2 μm or more and 1 μm or less.

13. The method of manufacturing the silicon carbide epitaxial substrate according to claim 9, wherein the first C/Si ratio is 1.1 or more and 1.8 or less.

14. The method of manufacturing the silicon carbide epitaxial substrate according to claim 9, wherein the second C/Si ratio is 0.85 or more and 0.95 or less.
